(19) United States
(12) Patent Application Publication
(10) Pub. No.: US 2015/0116687 A1
(43) Pub. Date: Apr. 30, 2015

(54) MICROPROCESSING SYSTEM, MICROPROCESSING APPARATUS, AND MICROPROCESSING METHOD

(71) Applicant: Kabushiki Kaisha Toshiba, Minato-ku (JP)

(72) Inventor: Eiji YONEDA, Yokkaichi-shi (JP)

(73) Assignee: Kabushiki Kaisha Toshiba, Minato-ku (JP)

(21) Appl. No.: 14/285,683

(22) Filed: May 23, 2014

(30) Foreign Application Priority Data
Oct. 31, 2013 (JP) 2013-227248

(51) Int. Cl. G03F 7/20

(52) U.S. Cl. CPC G03F 7/70775
USPC 355/72

(57) ABSTRACT

According to one embodiment, a microprocessing system for transferring a concave-convex pattern of a template to a resist layer formed on a substrate by bringing the template with concave-convex formed close or pressing the template against the resist layer, the microprocessing system includes a microprocessing apparatus, and a control device. The microprocessing apparatus includes a stage unit capable of supporting the substrate, a chuck unit opposing the stage unit and capable of bringing the template close or pressing the template against the resist layer, a memory unit capable of storing a relationship between a pressing force of the template and a film thickness of the resist layer, and a control unit configured to control bringing close or pressing of the template to the resist layer. The control device corrects the relationship so that the film thickness distribution falls within a target distribution.

### CROSS-REFERENCE TO RELATED APPLICATIONS

This application is based upon and claims the benefit of priority from Japanese Patent Application No. 2013-227248, filed on Oct. 31, 2013; the entire contents of which are incorporated herein by reference.

### FIELD

Embodiments described herein relate generally to a microprocessing system, a microprocessing apparatus, and a microprocessing method.

### BACKGROUND

With the progress of miniaturization and integration of semiconductor devices, it is required to increase the accuracy of photolithography apparatus. However, photolithography technology has a resolution limit in microprocessing of several tens of nanometers or less. Hence, nanoimprinting is drawing attention as a next-generation microprocessing. In the nanoimprinting, a resist layer is formed on an underlayer, and a template having a concave-convex pattern is pressed against the resist layer to form a concave-convex pattern on the resist layer, for example. Here, the operation of pressing the template against the resist layer is called a shot, and a shot of one time is called one shot, for example.

However, when the template and the underlayer are not parallel, the concave-convex pattern varies in one shot, and this may adversely affect the etching conditions in the next step.

### BRIEF DESCRIPTION OF THE DRAWINGS

FIG. 1A is a schematic plan view of a template that can be mounted in the microprocessing apparatus according to a first embodiment and a chuck unit for supporting the template, and FIG. 1B is a schematic view showing the microprocessing apparatus according to the first embodiment;

FIG. 2 is a system configuration diagram showing the microprocessing system according to the first embodiment;

FIG. 3 is a flow chart showing the microprocessing method according to the first embodiment;

FIG. 4A is a graph showing the relationship between pressing force and film thickness, and FIG. 4B is a schematic cross-sectional view showing the resist layer pressed by the template;

FIG. 5 is a schematic plan view showing the partitioning of the resist layer;

FIG. 6 is a schematic plan view showing a method for obtaining the film thickness distribution of the resist layer;

FIG. 7 is a schematic view showing a microprocessing apparatus according to a modification example of the first embodiment;

FIG. 8 is a flow chart showing a microprocessing method according to the modification example of the first embodiment;

FIG. 9A is a schematic plan view of a template that can be provided in a microprocessing apparatus according to a second embodiment and a chuck unit for supporting the template, and FIG. 9B is a schematic view showing the microprocessing apparatus according to the second embodiment; and

FIG. 10 is a flow chart showing a microprocessing method according to the second embodiment.

### DETAILED DESCRIPTION

According to one embodiment, a microprocessing system for transferring a concave-convex pattern of a template to a resist layer formed on a substrate by bringing the template with concave-convex formed close to the resist layer or pressing the template with concave-convex formed against the resist layer, the microprocessing system includes a microprocessing apparatus, and a control device. The microprocessing apparatus includes a stage unit capable of supporting the substrate, a chuck unit opposing the stage unit and capable of bringing the template close to the resist layer or pressing the template against the resist layer while supporting the template, a memory unit capable of storing a relationship between a pressing force of the template brought close to or pressed against the resist layer and a film thickness of the resist layer that the template is brought close to or pressed against, and a control unit configured to control bringing close or pressing of the template to the resist layer. The control device is configured to correct the relationship so that a film thickness distribution falls within a target distribution when the film thickness distribution of the resist layer that the template is brought close to or pressed against is out of the target distribution.

Various embodiments will be described hereinafter with reference to the accompanying drawings. In the following description, identical components are marked with the same reference numerals, and a description of components once described is omitted as appropriate.

### First Embodiment

First, before the entire system for microprocessing (microprocessing system) is described, a microprocessing apparatus 1A incorporated into the microprocessing system is described.

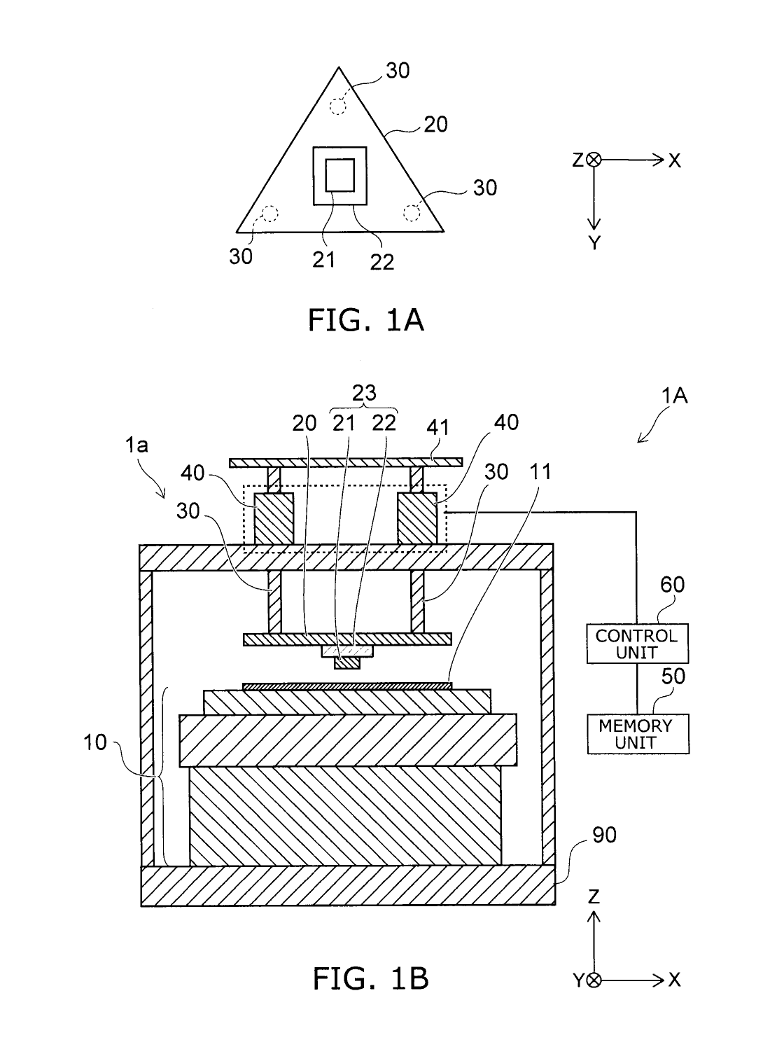

FIG. 1A is a schematic plan view of a template that can be mounted in the microprocessing apparatus according to a first embodiment and a chuck unit for supporting the template, and FIG. 1B is a schematic view showing the microprocessing apparatus according to the first embodiment.

The microprocessing apparatus 1A according to the first embodiment is an apparatus that can perform nanoimprint processing on a resist layer. The microprocessing apparatus 1A includes a main body is including a stage unit 10, a template chuck unit 20 (hereinafter, simply a chuck unit 20), a plurality of guides 30, and an actuator unit 40, a memory unit 50, and a control unit 60. The main body 1a further includes a cabinet 90 surrounding the stage unit 10 and the chuck unit 20. Although not shown, in addition to them, a unit for applying a resist and a light source for curing the resist are provided.

The microprocessing apparatus 1A can transfer the concave-convex pattern of a template 23 to a resist layer on a substrate 11 by a method in which the template 23 with the concave-convex pattern formed is pressed against or brought close to the resist layer. The resist layer contains a curable resin. In the embodiment, the operation in which the template 23 is pressed against or brought close to the resist layer is defined simply as “pressing” operation.

The stage unit 10 supports the substrate 11. The stage unit 10 has a vacuum chuck mechanism, for example. The chuck unit 20 opposes the stage unit 10. The chuck unit 20 can support and fix the template 23 by vacuum attraction, for example. The planar shape of the chuck unit 20 is a polygon, and a triangular chuck unit 20 is illustrated in FIG. 1A as an example. The template 23 includes a transparent plate 22 with no pattern formed and a pattern unit 21. A concave-convex pattern of nano-order is formed on the pattern unit 21.

The plurality of guides 30 are connected to peripheral portions of the chuck unit 20 on the opposite side to the stage unit 10. Each of the plurality of guides 30 is what is called a guide rod. The guide 30 supports the corner of the chuck unit 20. For example, each of the three guides 30 is connected to the vicinity of the vertex of the triangular chuck unit 20 to support the corner of the chuck unit 20. The actuator unit 40 can control the pressing force whereby the template 23 presses the resist layer via the plurality of guides 30. Each of the three guides 30 is connected to a support 41 provided outside the cabinet 90.

In the memory unit 50, the relationship between the pressing force of the template that presses the resist layer and the film thickness of the resist layer pressed by the template 23 (a first relationship) is stored. The relationship is made into a database for each of various product groups or each of types of substrate. The data showing the relationship are referred to as data (1). Data (1) are set to the same value for all shots in the initial stage. Data (1) are corrected as appropriate by feedback afterward. This is described in detail later.

The control unit 60 can partition the surface of the substrate 11 into a plurality of regions. The control unit 60 can use the relationship mentioned above stored in the memory unit 50 to instruct the actuator unit 40 on the pressing force distribution of the template 23 in each of the plurality of regions. When correction to the relationship mentioned above is required by a control device 600 described later, the control unit 60 can use the relationship mentioned above after correction to instruct the actuator 40 on the pressing force distribution of the template 23 in each of the plurality of regions.

The actuator unit 40 is provided outside the cabinet 90, for example. The guide 30 pierces the actuator unit 40. The actuator unit 40 is controlled by a voltage signal (or a current signal) received from the control unit 60. The guide 30 piercing the actuator unit 40 is controlled by the actuator unit 40.

Each of the plurality of guides 30 can move in the Z-direction by being driven by the actuator unit 40. In other words, each of the plurality of guides 30 slides in the vertical direction. Thereby, the template 23 supported by the chuck unit 20 moves vertically. By the template 23 moving downward, the template 23 can be pressed against the resist layer formed on the substrate 11. At this time, it is preferable that the same force be applied by the actuator unit 40 to the plurality of guides 30. Thereby, the template 23 can be pressed against the resist layer with the same pressure in the center and the outer peripheral portion of the template 23.

However, actually it is not necessarily the case that the same force is applied by the actuator unit 40 to the plurality of guides 30. This is because there is a subtle difference in the coefficient of friction between the actuator unit 40 and the guide 30, the actuator unit 40 and the guide 30 have dimensional errors etc., or the like. When the same force is not applied by the actuator unit 40 to the plurality of guides 30, there is a distribution in pressing force. In the embodiment, the force applied to each of the plurality of guides 30 is corrected by a microprocessing system 100 described below.

An overview of the microprocessing system 100 including the microprocessing apparatus 1A will now be described.

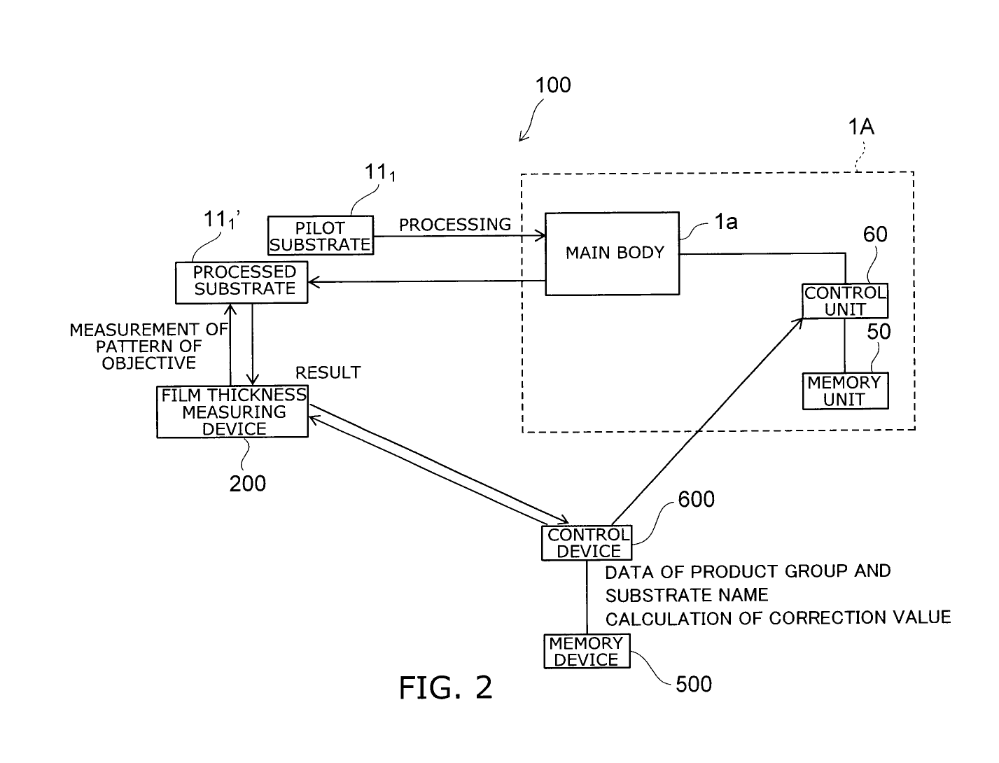

FIG. 2 is a system configuration diagram showing the microprocessing system according to the first embodiment.

The case where one lot of substrates are processed is described as an example. One lot has a plurality of substrates 11 (substrates 11₁, 11₂, . . . 11ₙ₋₁, 11ₙ).

One lot of substrates 11 belong to one of the various product groups or one of the types of substrate. Data (1) are determined beforehand for each of the product groups or each of the types of substrate. The information of the product group of the substrate, the name of the substrate, etc., and data showing the relationship between pressing force and film thickness corresponding to that information are determined beforehand, for example.

Of the plurality of substrates 11, the primal substrate 11₁ (for example, the substrate of the first sheet in one lot) is put into the microprocessing apparatus 1A and undergoes nanoimprint processing under the standard pressing force. That is, nanoimprint processing is performed in each of the plurality of regions of the primal substrate 11₁.

At this time, the pressing force distribution data of the nanoimprint processing for each region using the primal substrate 11₁ are stored in the memory unit 50 via the control unit 60 of the microprocessing apparatus 1A. The pressing force distribution data are obtained based on a voltage (or a current) applied to the actuator unit 40, for example. The stored pressing force distribution data are referred to as data (2). At this time, also the information of the product group, the substrate name, etc. of the substrate 11₁ is transmitted together to the memory unit 50 via the control unit 60.

Next, the processed substrate that has undergone nanoimprint processing (this is referred to as a substrate 11₁′) is taken out of the microprocessing apparatus 1A. Subsequently, the processed substrate 11₁′ is set on a film thickness measuring device 200 (for example, an ellipsometer), and the film thickness distribution of the pattern to be measured in each of the plurality of regions that have undergone nanoimprint processing under the standard pressure is measured. The measured film thickness distribution data are stored in a memory device 500 via the control device 600 provided in the microprocessing system 100.

In this stage, the film thickness distribution data of the primal substrate 11₁ (the processed substrate 11₁′) are stored in the memory device 500. They are referred to as data (3).

The control device 600 assesses whether data (3) are within the target value or not. If data (3) are not within the target value, the correction operation illustrated below is performed.

First, the control device 600 accesses the control unit 60 of the microprocessing apparatus 1A to call up data (1) and data (2) stored in the memory unit 50 of the microprocessing apparatus 1A, and stores these data in the memory device 500.

In this stage, data (1) to (3) are stored in the memory device 500.

Next, the control device 600 compares the film thickness distribution determined from the relationship between data (2) and data (1), with data (3), and corrects data (1). Subsequently, the corrected data are transmitted by the control device 600 to the memory unit 50 via the control unit 60 of the microprocessing apparatus 1A.

Thus, data (1) are corrected by feedback to an optimum value for each shot.

In this stage, a new corrected relationship between the pressing force of the template and the film thickness of the resist layer is stored in the memory unit 50 of the microprocessing apparatus 1A. That is, feedback control is made by the control device 600. The control unit 60 of the microprocessing apparatus 1A calls up the new relationship after correction from the memory unit 50, and performs the nanoimprinting of the next substrate 11₂ to the substrate 11ₙ, which are the same product, on the basis of the relationship after correction.

Next, a microprocessing method using the microprocessing system 100 will now described.

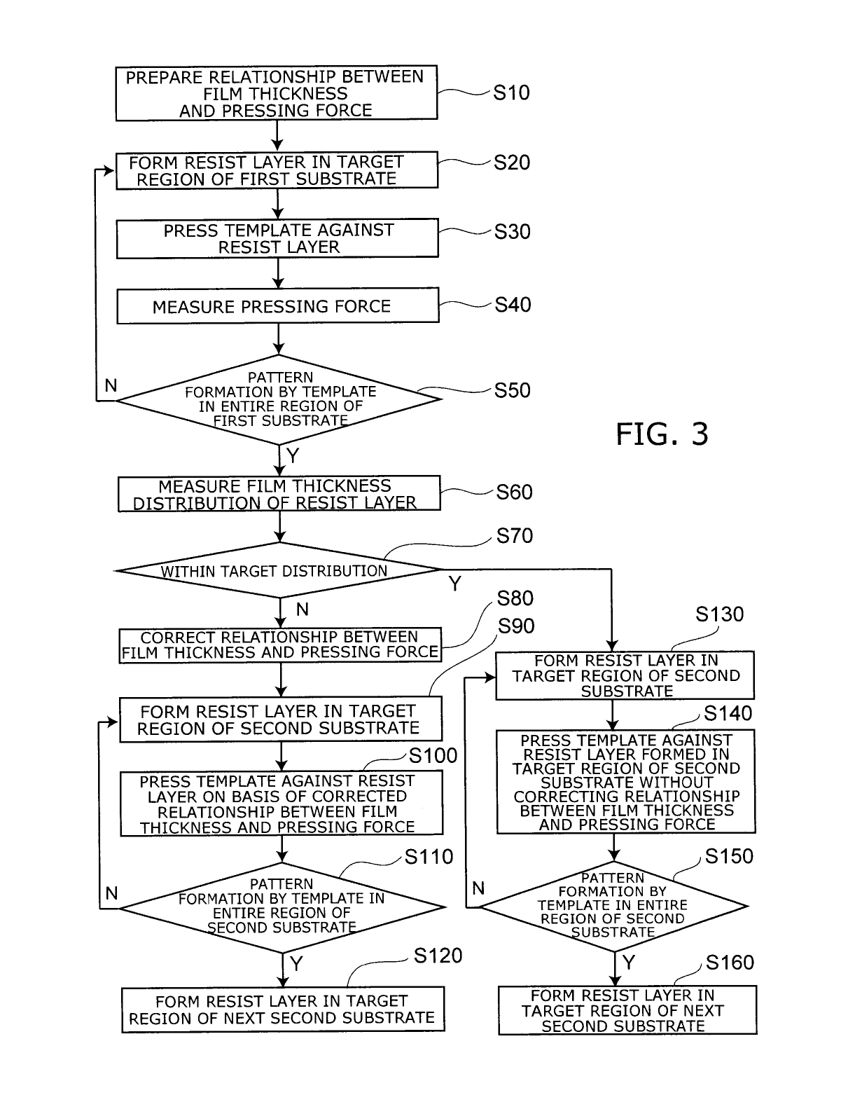

FIG. 3 is a flow chart showing the microprocessing method according to the first embodiment.

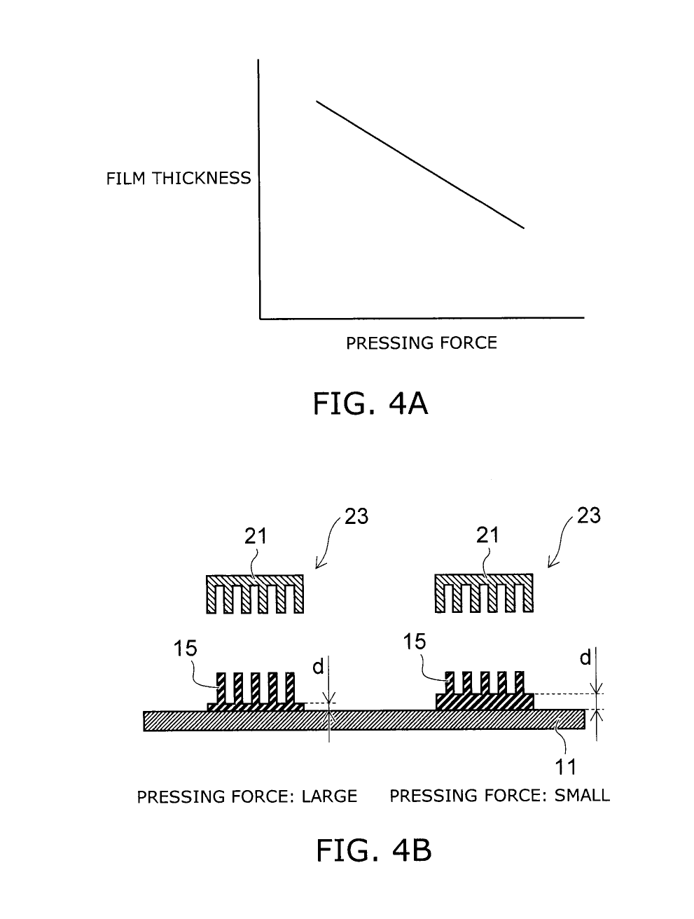

FIG. 4A is a graph showing the relationship between pressing force and film thickness, and FIG. 4B is a schematic cross-sectional view showing the resist layer pressed by the template.

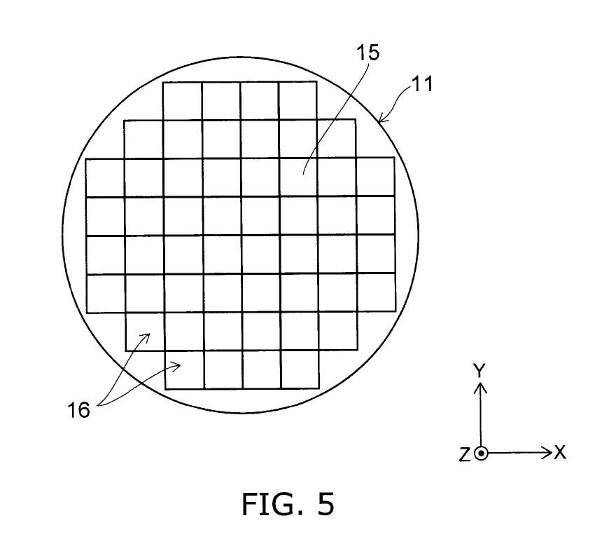

FIG. 5 is a schematic plan view showing the partitioning of the resist layer.

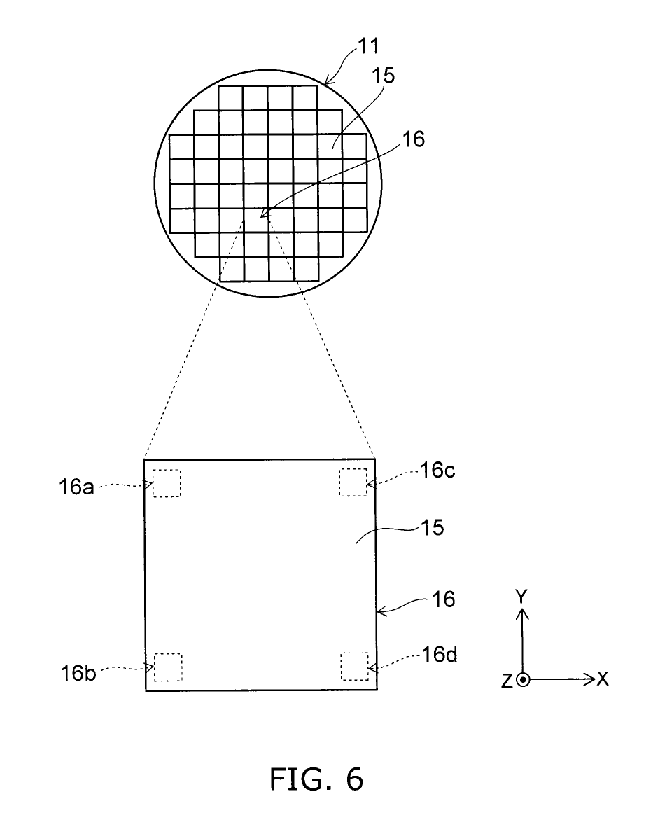

FIG. 6 is a schematic plan view showing a method for obtaining the film thickness distribution of the resist layer.

The microprocessing method according to the first embodiment will now be described using FIG. 4A to FIG. 6 with reference to the flow chart shown in FIG. 3.

First, as a precondition, the relationship between the pressing force of the template that presses the resist layer and the film thickness of the resist layer pressed by the template 23 is prepared for various product groups and types of substrate (step S10). In other words, data (1) showing the relationship mentioned above for each of the various product groups and each of the types of substrate are made into a database.

As shown in FIG. 4A and FIG. 4B, the film thickness d in an arbitrary position of a resist layer 15 tends to decrease as the pressing force whereby the template 23 presses the resist layer 15 increases, for example. The film thickness d of the resist layer 15 is preferably uniform in one shot. This is because, if the film thickness distribution of the resist layer 15 varies in one shot, also the pattern of an underlayer to which the pattern of the resist layer 15 is transferred varies as a matter of course.

The relationship between pressing force and film thickness for each of the various product groups and each of the types of substrate is prepared by experiment, simulation, or the like. The relationship between pressing force and film thickness is stored in the memory unit 50 or the memory device 500. The control device 600 can also access the control unit 50 to call up the relationship between pressing force and film thickness of a specific substrate of a specific product from the memory unit 50 at any time.

Next, a plurality of substrates 11 of a specific type are prepared in a specific product group. The plurality of substrates 11 (substrates 11₁, 11₂, . . . 11ₙ₋₁, 11ₙ) are taken as one lot. The primal substrate 11₁ (a first substrate) in the one lot is placed on the stage unit 10 of the microprocessing apparatus 1A. Subsequently, as shown in FIG. 5, the substrate 11₁ is partitioned into a plurality of regions 16 by the control unit 60. The regions 16 are provided longitudinally and latitudinally on the surface of the substrate 11₁. Subsequently, the resist layer 15 is formed in a target region 16 of the substrate 11₁ by the inkjet application method, for example (step S20).

Next, the template 23 is pressed with a prescribed pressing force distribution against the resist layer 15 formed in the target region 16 of the substrate 11₁ (step S30). Thereby, as shown in FIG. 4B, the pattern of the pattern unit 21 is transferred to the resist layer 15.

Here, the pressing force applied to the template 23 from the plurality of actuator units 40 is controlled by the control unit 60. The pressing force of the plurality of actuator units 40, that is, the pressing force distribution with which the resist layer 15 is pressed is measured by the control unit 60 (step S40). Then, the data of the pressing force distribution are stored in the memory unit 50 by the control unit 60.

Next, it is assessed whether or not one shot has been performed in the entire target region of the substrate 11₁. For example, it is assessed whether or not the patterning of the resist layer 15 by the template 23 has been performed in the entire target region of the substrate 11₁ (step S50).

In the case where the patterning of the resist layer 15 by the template 23 has not been performed in the entire target region, the flow proceeds to the next step S60.

Next, the primal substrate 11₁ is taken out of the microprocessing apparatus 1A. Then, as shown in FIG. 5, the film thickness distribution of the resist layer 15 in each region 16 after the template 23 is pressed is measured by the film thickness measuring device 200 (step S60).

Places 16a to 16d in the four corners of the region 16 are selected, and the film thicknesses of the resist layer 15 in places 16a to 16d are measured, as an example.

When the film thickness d is equal in places 16a to 16d shown in FIG. 6, the film thickness d is uniform in the X-direction and the Y-direction in the one region 16, for example. When the film thicknesses d in places 16a to 16d are different, the film thickness d has a distribution in the X-direction or the Y-direction in the one region 16.

The film thickness differences Δd1 between place 16a and place 16b, between place 16a and place 16c, between place 16a and place 16d, between place 16b and place 16c, between place 16b and place 16d, and between place 16c and place 16d are calculated, for example. Then, the data of the film thickness difference Δd1 in each region 16 are transmitted to the control device 600, and are stored in the memory device 500 as film thickness distribution data.

In addition to the film thickness difference Δd1, the average value of film thickness calculated using a plurality of substrates 11 or the amount of shift in film thickness from the target film thickness Δd2 may be stored in the memory device 500. In the embodiment, the film thickness differences Δd1, Δd2, etc. are collectively referred to as film thickness distribution.

Next, the control device 600 assesses whether or not the film thickness distribution in each of the plurality of regions 16 stored in the memory device 500 is within the target value (step S70).

In the case where the film thickness distribution in one of the plurality of regions 16 is out of the target distribution, the control device 600 corrects the relationship between pressing force and film thickness using the film thickness distribution stored in the memory device 500, the relationship between pressing force and film thickness called up from the memory unit 50, and the pressing force distribution called up from the memory unit 50 so that the film thickness distribution falls within the target distribution in the one of the plurality of regions 16 (step S80). Then, the control device 600 stores the corrected relationship between pressing force and film thickness in the memory device 500 or the memory unit 50 of the microprocessing apparatus 1A via the control unit 60.

Next, the actual substrates 11₂ to 11ₙ (second substrates) to be processed after the primal substrate 11₁ are prepared. Then, of the actual substrates 11₂ to 11ₙ, the substrate 11₂ to be processed next after the primal substrate 11₁ is placed on the stage unit 10 of the microprocessing apparatus 1A. Subsequently, the surface of the substrate 11₂ is partitioned into a plurality of regions 16 by the control unit 60, and then the resist layer 15 is formed in a target region 16 of the substrate 11₂ by the inkjet application method, for example (step S90).

In the case where the relationship between pressing force and film thickness has been corrected in one of the plurality of regions 16 when the primal substrate 11₁ was used, the control unit 60 makes the control described below. For example, in the region 16 where correction has been made, when the template 23 is pressed against the resist layer 15 formed on the substrate 11₂, the control unit 60 makes the control of pressing the template 23 against the resist layer 15 on the basis of the corrected relationship between pressing force and film thickness (step S100).

Next, it is assessed whether or not the patterning of the resist layer 15 by the template 23 has been performed in the entire target region of the substrate 11₂ (step S110). In the case of not being performed in the entire target region, the flow returns to step S90 to continue the operation of forming the resist layer 15 in the target region 16 of the substrate 11₂.

In the case where the patterning of the resist layer 15 has been performed in the entire target region, the flow proceeds to the processing of the substrate 11₃ next after the substrate 11₂, and the resist layer 15 is formed in a target region 16 of the substrate 11₃ (step S120). After that, the processing performed on the substrate 11₂ is performed also on the substrate 11₃. Further, the processing performed on the substrate 11₂ is performed also on each of the substrates 11₄ to 11ₙ.

On the other hand, in the case where in step S70 it has been determined by the control device 600 that the film thickness distribution is within the target distribution, the resist layer 15 is formed in a target region 16 of the substrate 11₂ (step S130), and then the resist layer 15 formed in the target region 16 is pressed by the template 23 without the relationship between pressing force and film thickness being corrected (step S140).

Next, it is assessed whether or not the patterning of the resist layer 15 by the template 23 has been performed in the entire target region of the substrate 11₂ (step S150). In the case where the patterning of the resist layer 15 has not been performed in the entire target region, the flow returns to step S130, and the resist layer 15 is formed in the target region 16 of the substrate 11₂.

In the case where the patterning of the resist layer 15 has been performed in the entire target region, the flow proceeds to the processing of the substrate 11₃ next after the substrate 11₂, and the resist layer 15 is formed in a target region 16 of the substrate 11₃ (step S160). After that, the processing performed on the substrate 11₂ is performed also on the substrate 11₃. Further, the processing performed on the substrate 11₂ is performed also on each of the substrates 11₄ to 11ₙ.

The correction to the pressing force distribution may not be made for each lot but be made while nanoimprint processing is performed on the actual substrates 11₂ to 11ₙ. In this method, a substrate 11ₘ (2≦m<n) that is currently processed serves as the primal substrate in the lot, and the remaining substrates 11ₘ₊₁ to 11ₙ to be processed after the substrate 11ₘ serve as the actual substrates. Thus, also the method in which the relationship between pressing force and film thickness is corrected in the course of the lot, not for each lot, is included in the embodiment.

### Variation of the First Embodiment

In addition to the method in which the film thickness distribution of the primal substrate 11₁ is measured and the measurement result is used to correct the relationship between pressing force and film thickness when the substrates 11₂ to 11ₙ other than the substrate 11₁ are processed, the film thickness of the resist layer 15 of an arbitrary substrate 11 out of the plurality of substrates 11 may be measured in-situ and the relationship between pressing force and film thickness in each shot may be corrected one after another.

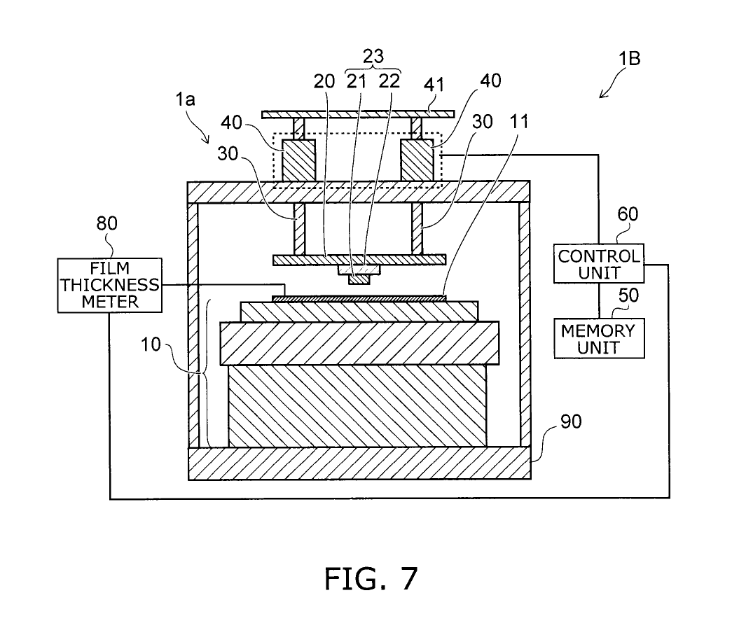

FIG. 7 is a schematic view showing a microprocessing apparatus according to a modification example of the first embodiment.

In the microprocessing apparatus 1A shown in FIG. 7, a film thickness meter 80 that can measure the film thickness of the resist layer 15 formed in a target region 16 of the substrate 11 in-situ is installed. The control device 600 and the memory device 500, which are not shown, are connected to the microprocessing apparatus 1A.

The film thickness meter 80 is controlled by the control unit 60 or the control device 600. The data of the film thickness distribution measured by the film thickness meter 80 are stored in the memory unit 50 via the memory device 500 and the control unit 60.

The relationship between pressing force and film thickness, that is, data (1) are made into a database in the memory unit 50 or the memory device 500 for each of the various product groups and each of the types of substrate beforehand.

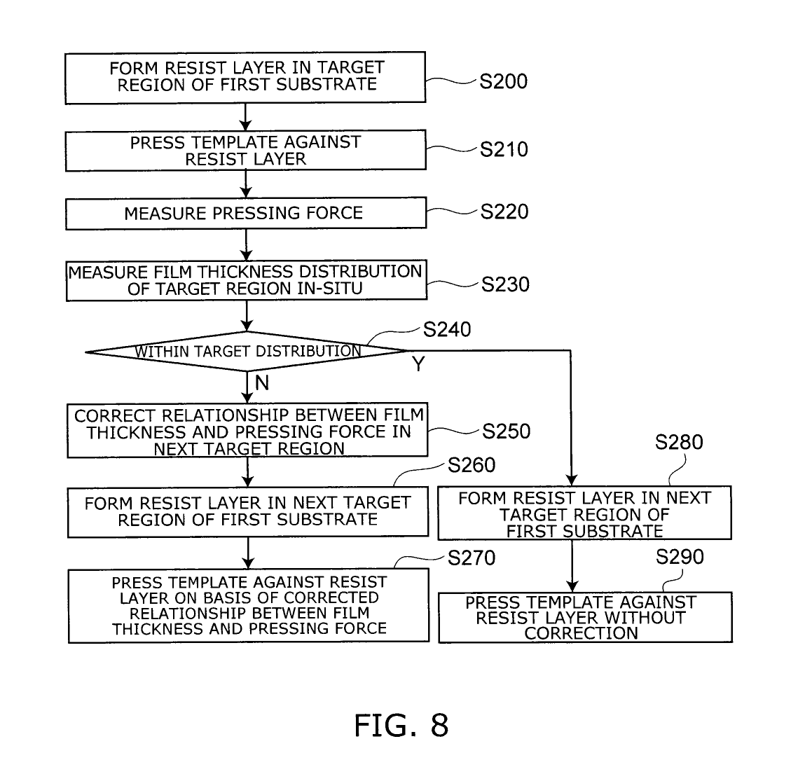

FIG. 8 is a flow chart showing a microprocessing method according to the modification example of the first embodiment.

First, the resist layer 15 is formed in a target region 16 of the substrate 11 by the inkjet application method, for example (step S200).

Next, the template 23 is pressed with a prescribed pressing force distribution against the resist layer 15 formed in the target region 16 (step S210).

Next, the pressing force distribution with which the resist layer 15 is pressed is measured by the control unit 60 (step S220). The pressing force of each of the plurality of actuator units 40 at this time is stored in the memory unit 50 as pressing force distribution data.

Next, the film thickness distribution of the resist layer 15 after the template 23 is pressed is measured in-situ by the film thickness meter 80 (step S230). The film thickness distribution data are stored in the memory device 500 or the memory unit 50.

Next, the control device 600 assesses whether or not the film thickness distribution stored in the memory device 500 is within the target value (step S240).

Next, in the case where the film thickness distribution is out of the target distribution, the control device 600 corrects the relationship between pressing force and film thickness using the film thickness distribution stored in the memory device 500, the pressing force distribution called up from the memory unit 50, and the relationship between pressing force and film thickness called up from the memory unit 50, that is, data (1) so that the film thickness distribution in the next target region 16 falls within the target distribution (step S250). The control device 600 stores the corrected relationship between pressing force and film thickness in the memory device 500 or the memory unit 50 of the microprocessing apparatus 1B via the control unit 60.

Next, the resist layer 15 is formed in the next target region 16 of the substrate 11 by the inkjet application method, for example (step S260).

Next, in the target region 16, the template 23 is pressed against the resist layer 15 on the basis of the corrected relationship between pressing force and film thickness (step S270).

On the other hand, in the case where in step 240 it has been determined by the control device 600 that the film thickness distribution is within the target distribution, the resist layer 15 is formed in the next target region 16 of the substrate 11 (step S280), and then the resist layer 15 formed in the next target region 16 is pressed by the template 23 without the relationship between pressing force and film thickness being corrected (step S290).

FIG. 8 described above illustrates a method in which the film thickness distribution is measured in-situ for each one shot to enable the relationship between pressing force and film thickness to be corrected for each one shot. Other than this, in the embodiment, it is also possible to perform a plurality of shots and then find the average of film thickness distribution of the plurality of shots; and when the average of film thickness distribution is out of the target value, the relationship between pressing force and film thickness may be corrected.

By the microprocessing system 100 and the microprocessing method described above, the variation in the thickness of the resist layer 15 when nanoimprint processing is performed on the resist layer 15 by the template 23 is surely suppressed.

### Second Embodiment

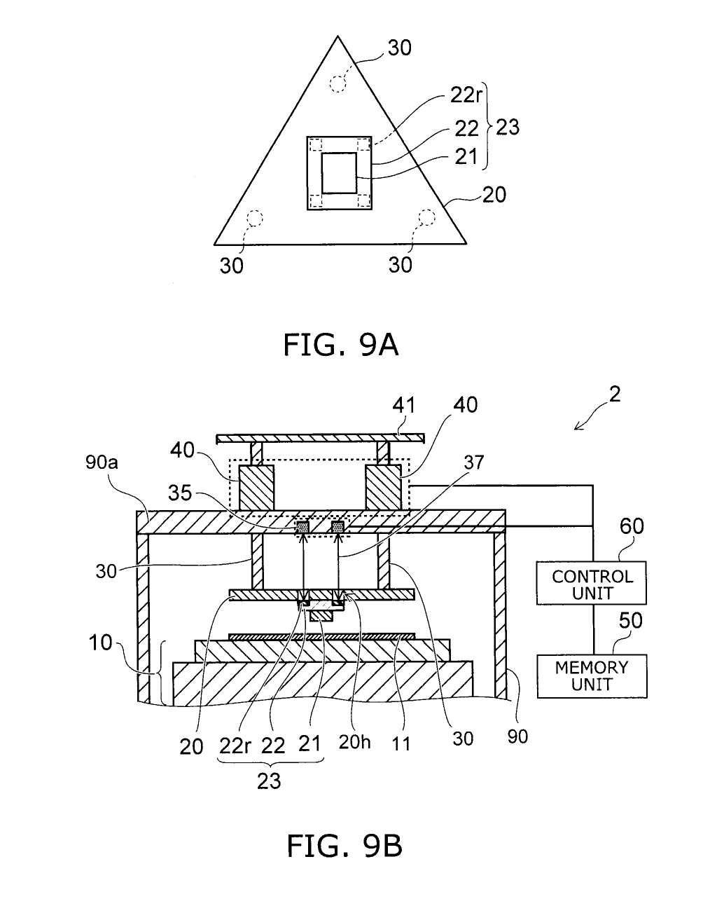

FIG. 9A is a schematic plan view of a template that can be provided in a microprocessing apparatus according to a second embodiment and a chuck unit for supporting the template, and FIG. 9B is a schematic view showing the microprocessing apparatus according to the second embodiment.

Also a microprocessing apparatus 2 described below may be used as the microprocessing apparatus incorporated into the microprocessing system 100.

The microprocessing apparatus 2 according to the second embodiment includes the stage unit 10, the chuck unit 20, a plurality of guides 30, the actuator unit 40, a plurality of laser distance meters (distance meters) 35, the memory unit 50, and the control unit 60.

In the microprocessing apparatus 2, the plurality of laser distance meters 35 are provided in addition to the configuration of the microprocessing apparatus 1 described above. Each of the plurality of laser distance meters 35 is provided at the upper cover 90a of the cabinet 90.

In the template 23 of the microprocessing apparatus 2, reflection films 22r are provided on the side of the surface on the opposite side to the surface on which the pattern unit 21 (concave-convex pattern) is formed. Each of the plurality of reflection films 22r is provided in each of the four corners of the template 23, for example. Through holes 20h are provided in the chuck unit 20.

In the microprocessing apparatus 2, the stage unit 10 is fixed in the cabinet 90, and thereby the distance between an arbitrary position of the substrate 11 placed on the stage unit 10 and an arbitrary position of the upper cover 90a of the cabinet 90 above the substrate 11 is determined beforehand. The laser distance meter 35 applies laser light 37 toward the reflection film 22r via the through hole 20h, and receives laser light 37 reflected by the reflection film 22r. The laser distance meter 35 can measure distance by the phase difference measurement method using reflected light and incident light of the laser light 37. The inclination of the template 23 and the height from the substrate 11 can be determined by the laser distance meter 35.

Specifically, the distance between each of the four corners of the template 23 and the upper cover 90a above each of the four corners of the template 23 can be measured, for example. The inclination of the template 23 can be measured from the information of the four distances.

The distance between an arbitrary position of the substrate 11 and an arbitrary position of the upper cover 90a of the cabinet 90 above the substrate 11 is already known. By measuring the distance between each of the four corners of the template 23 and the upper cover 90a above each of the four corners, the distance between each of the four corners of the template 23 and the substrate 11 can be calculated. In other words, by using the laser distance meter 35, the height from the substrate 11 of each of the four corners of the template 23 can be measured. In the embodiment, the distribution of the distances between the four corners of the template 23 and the upper cover 90a above the four corners of the template 23, the distribution of the inclination of the template 23, the distribution of the heights from the substrate 11 of the four corners of the template, etc. may be collectively referred to as “distance distribution.”

The information of distance distribution measured using the plurality of laser distance meters 35 can be stored in the memory unit 50 or the memory device 500 together with the pressing force distribution. The control device 600 can correct the relationships between pressing force, film thickness, and distance distribution, which include distance distribution in addition to the relationship between pressing force and film thickness, and can store the corrected relationships in the memory unit 50 via the control unit 60.

The relationships between distance distribution, pressing force, and film thickness for various product groups and types of substrate are stored in the memory unit 50 beforehand. When the relationships have been corrected by the control device 600, the relationships stored in the memory unit 50 are rewritten by the control device 600.

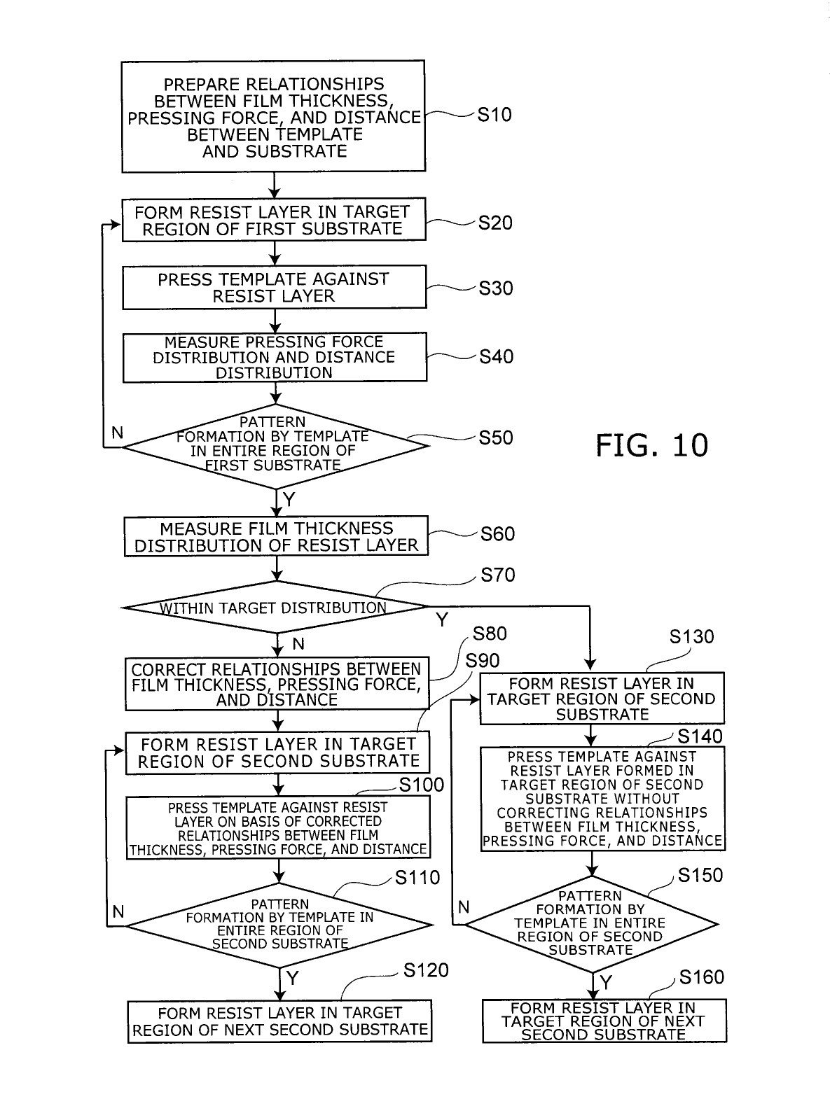

FIG. 10 is a flow chart showing a microprocessing method according to the second embodiment.

In the microprocessing method according to the second embodiment, the inclination of the template 23 and distance distribution such as the distribution of the height from the substrate 11 are introduced in addition to the film thickness distribution of the resist layer 15; thus, the pressing force distribution with which the template 23 presses the resist layer 15 can be corrected with better accuracy.

First, as a precondition, the relationships between the film thickness of the resist layer 15 pressed by the template 23, the pressing force distribution of the template that presses the resist layer 15, and the distance distribution between the template 23 and the substrate 11 detected by the laser distance meter 35 are prepared for various product groups and types of substrate (step S10). In other words, data showing the relationships between pressing force, film thickness, and distance distribution for each of the various product groups and each of the types of substrate are made into a database.

That is, in the second embodiment, in addition to the relationship between pressing force and film thickness according to the first embodiment, the data of the distance distribution between the template 23 and the substrate 11 detected by the laser distance meter 35 and the data of the pressing force of the template that presses the resist layer 15 are made into a database for each shot.

Next, one lot (substrates 11₁, 11₂, . . . 11ₙ₋₁, 11ₙ) in which a plurality of substrates 11 of a specific type in a specific product group are collected is prepared. Subsequently, the primal substrate 11₁ (the first substrate) in the one lot is placed on the stage unit 10 of the microprocessing apparatus 2. Subsequently, the surface of the substrate 11₁ is partitioned into a plurality of regions 16 by the control unit 60. Subsequently, the resist layer 15 is formed in a target region 16 of the substrate 11₁ by the inkjet application method, for example (step S20).

Next, the template 23 is pressed with a prescribed pressing force distribution against the resist layer 15 formed in the target region 16 of the substrate 11₁ (step S30). At this time, the data of the pressing force distribution of the plurality of actuator units 40 and the data of distance distribution are measured by the control unit 60 (step S40). In other words, the pressing force distribution of the template 23 that presses the resist layer 15, the distance between the template 23 and the cabinet 90 and the inclination of the template 23 when the resist layer 15 is pressed, and distance distribution such as the height distribution from the substrate 11 from the distance between the template 23 and the cabinet 90 are measured. These data are stored in the memory unit 50 by the control unit 60.

Thus, in the microprocessing method according to the second embodiment, before the film thickness distribution of the resist layer 15 is determined, laser light is applied toward the reflection film 22r of the template 23, and reflected light and incident light of the laser light are used to find the distance between the template 23 and the upper cover 90a of the cabinet 90, the inclination of the template 23, and distance distribution such as the distribution of the height from the substrate 11 obtained from the distance between the template 23 and the cabinet 90.

Next, it is assessed whether or not the resist layer 15 patterned by the template 23 has been formed in the entire target region of the substrate 11 (step S50).

In the case where the patterning of the resist layer 15 is not performed in the entire target region, the flow returns to step S20 to continue the operation of patterning by the template 23. In the case of being formed in the entire target region, the flow proceeds to the next step S60.

Next, the primal substrate 11₁ is taken out of the microprocessing apparatus 2. Then, the film thickness distribution of the resist layer 15 after the template 23 is pressed is determined by the film thickness measuring device 200 (for example, an ellipsometer) (step S40). Also at this time, the data of the film thickness difference Δd1 described above are stored in the memory device 500. The film thickness distribution data herein are film thickness distribution data as a general term including not only Δd1 but also Δd2 described above.

Next, the control device 600 assesses whether or not the film thickness distribution for each of the plurality of regions 16 is within the target value, using the film thickness distribution and the relationships between film thickness, distance, and pressing force stored in the memory device 500, and the pressing force distribution and the distance distribution called up from the memory unit 50 (step S70).

In the case where the film thickness distribution in one of the plurality of regions 16 is out of the target distribution, the control device 600 corrects the relationships between pressing force, film thickness, and distance using the film thickness distribution stored in the memory device 500, and the relationship between pressing force and film thickness, the pressing force distribution, and the distance distribution called up from the memory unit 50 so that the film thickness distribution falls within the target distribution in the one of the plurality of regions 16 (step S80).

Then, the control device 600 stores the corrected relationships between pressing force, film thickness, and distance distribution (first relationships) in the memory device 500 or the memory unit 50 of the microprocessing apparatus 2 via the control unit 60.

Next, the actual substrates 11₂ to 11ₙ (the second substrates) to be processed after the primal substrate 11₁ are prepared. Then, the substrate 11₂ out of the actual substrates 11₂ to 11ₙ is placed on the stage unit 10 of the microprocessing apparatus 2. Subsequently, the surface of the substrate 11₂ is partitioned into a plurality of regions 16 by the control unit 60, and then the resist layer 15 is formed in a target region 16 of the substrate 11₂ by the inkjet application method, for example (step S90).

Next, in the case where the relationships between pressing force, film thickness, and distance have been corrected in one of the plurality of regions 16 when the primal substrate 11₁ was used, the control unit 60 makes the control illustrated below. For example, in the region 16 where correction has been made, when the template 23 is pressed against the resist layer 15 formed on the substrate 11₂, the control unit 60 makes the control of pressing the template 23 against the resist layer 15 on the basis of the corrected relationships between film thickness, pressing force, and distance (step S100).

Next, it is assessed whether or not the patterning of the resist layer 15 by the template 23 has been performed in the entire target region of the substrate 11₂ (step S110). In the case of not being performed in the entire target region, the flow returns to step S90 to continue the operation of forming the resist layer 15 in the target region 16 of the substrate 11₂.

In the case where the patterning of the resist layer 15 has been performed in the entire target region, the flow proceeds to the processing of the substrate 11₃ next after the substrate 11₂, and the resist layer 15 is formed in a target region 16 of the substrate 11₃ (step S120). After that, the processing performed on the substrate 11₂ is performed also on the substrate 11₃. Further, the processing performed on the substrate 11₂ is performed also on each of the substrates 11₄ to 11ₙ.

In the case where in step S70 it has been determined by the control device 600 that the film thickness distribution is within the target distribution, the resist layer 15 is formed in a target region 16 of the substrate 11₂ (step S130), and then the resist layer 15 formed in the target region 16 is pressed by the template 23 without the relationships between pressing force, film thickness, and distance being corrected (step S140).

Next, it is assessed whether or not the patterning of the resist layer 15 by the template 23 has been performed in the entire target region of the substrate 11₂ (step S150). In the case where the patterning of the resist layer 15 has not been performed in the entire target region, the flow returns to step S130, and the resist layer 15 is formed in the target region 16 of the substrate 11₂.

In the case where the patterning of the resist layer 15 has been performed in the entire target region, the flow proceeds to the processing of the substrate 11₃ next after the substrate 11₂, and the resist layer 15 is formed in a target region 16 of the substrate 11₃ (step S160). After that, the processing performed on the substrate 11₂ is performed also on the substrate 11₃. Further, the processing performed on the substrate 11₂ is performed also on each of the substrates 11₄ to 11ₙ.

In the second embodiment, when the pressing force of the template 23 is corrected, also distance distribution such as the distribution of the distance between the template 23 and the upper cover 90a, the inclination of the template 23, and the height from the substrate 11 of the template 23 is used as a parameter for correction.

In other words, in the second embodiment, an appropriate pressing force distribution is obtained through correcting the relationships between pressing force, film thickness, and distance, not obtaining an appropriate pressing force distribution through correcting the relationship composed of pressing force and film thickness. Consequently, the accuracy of correction to the pressing force distribution of the template 23 that presses the resist layer 15 is further increased.

The embodiment includes also a feedforward system, not limited to the feedback system described above.

Although the embodiments are described above with reference to the specific examples, the embodiments are not limited to these specific examples. That is, design modification appropriately made by a person skilled in the art in regard to the embodiments is within the scope of the embodiments to the extent that the features of the embodiments are included. Components and the disposition, the material, the condition, the shape, and the size or the like included in the specific examples are not limited to illustrations and can be changed appropriately.

The components included in the embodiments described above can be combined to the extent of technical feasibility and the combinations are included in the scope of the embodiments to the extent that the feature of the embodiments is included. Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A microprocessing system for transferring a concave-convex pattern of a template to a resist layer formed on a substrate by bringing the template with concave-convex formed close to the resist layer or pressing the template with concave-convex formed against the resist layer, the microprocessing system comprising:
a microprocessing apparatus including a stage unit capable of supporting the substrate, a chuck unit opposing the stage unit and capable of bringing the template close to the resist layer or pressing the template against the resist layer while supporting the template, a memory unit capable of storing a relationship between a pressing force of the template brought close to or pressed against the resist layer and a film thickness of the resist layer that the template is brought close to or pressed against, and a control unit configured to control bringing close or pressing of the template to the resist layer; and
a control device configured to correct the relationship so that a film thickness distribution falls within a target distribution when the film thickness distribution of the resist layer that the template is brought close to or pressed against is out of the target distribution.

2. The system according to claim 1, wherein
the microprocessing apparatus further includes a distance meter capable of measuring a distance distribution between the substrate and the template and
the memory unit is capable of storing relationships between the pressing force, the film thickness, and the distance distribution.

3. The system according to claim 2, wherein the distance meter measures the distance distribution by a phase difference measurement method utilizing reflected light and incident light of laser light.

4. The system according to claim 2, wherein the control device corrects relationships between the pressing force, the film thickness, and the distance distribution so that a film thickness distribution falls within a target distribution when the film thickness distribution of the resist layer that the template is brought close to or pressed against is out of the target distribution.

5. The system according to claim 1, wherein the film thickness distribution is determined from a film thickness difference between two corners out of four corners of the resist layer that the template is brought close to or pressed against.

6. The system according to claim 1, wherein the control unit controls bringing close or pressing of the template to the resist layer using corrected relationships between the pressing force, the film thickness, and the distance distribution.

7. A microprocessing apparatus for transferring a concave-convex pattern of a template to a resist layer formed on a substrate by bringing the template with concave-convex formed close to the resist layer or pressing the template with concave-convex formed against the resist layer, the microprocessing apparatus comprising:
a stage unit capable of supporting the substrate;
a chuck unit opposing the stage unit and capable of bringing the template close to the resist layer or pressing the template against the resist layer while supporting the template;
a distance meter capable of measuring a distance distribution between the substrate and the template;
a memory unit capable of storing relationships between a pressing force of the template brought close to or pressed against the resist layer, a film thickness of the resist layer that the template is brought close to or pressed against, and the distance distribution; and
a control unit configured to control bringing close or pressing of the template to the resist layer.

8. The apparatus according to claim 7, wherein the distance meter measures the distance distribution by a phase difference measurement method utilizing reflected light and incident light of laser light.

9. The apparatus according to claim 7, wherein the distance distribution between the substrate and the template is determined from a distance between each of four corners of the template and the substrate.

10. A microprocessing method for transferring a concave-convex pattern of a template to a resist layer formed on a plurality of substrates by bringing the template with concave-convex formed close to the resist layer or pressing the template with concave-convex formed against the resist layer, the microprocessing method comprising:
preparing data on a first relationship between a pressing force of the template brought close to or pressed against the resist layer and a film thickness of the resist layer that the template is brought close to or pressed against;
forming the resist layer on a first substrate of the plurality of substrates;
bringing the template close to the resist layer of the first substrate or pressing the template against the resist layer of the first substrate;
measuring a pressing force distribution of the template brought close or pressed;
determining a film thickness distribution of the resist layer after the template is brought close or pressed;
correcting the first relationship on a basis of the measured film thickness distribution, the measured pressing force distribution, and the first relationship so that the film thickness distribution falls within a target distribution when the film thickness distribution is out of the target distribution;
preparing a second substrate other than the first substrate of the plurality of substrates and forming the resist layer on the second substrate; and
bringing the template close to the resist layer of the second substrate or pressing the template against the resist layer of the second substrate while controlling on a basis of the corrected first relationship in a case where the first relationship has been corrected.

11. The method according to claim 10, wherein in the preparing data on the first relationship, the first relationship is relationships between the firm thickness, the pressing force, and a distance distribution between the substrate and the template.

12. The method according to claim 11, wherein in the measuring the pressing force, the distance distribution is measured in addition to the pressing force distribution.

13. The method according to claim 11, wherein the distance distribution is measured by a phase difference measurement method utilizing reflected light and incident light of laser light.

14. The method according to claim 10, wherein in the correcting the first relationship, the first relationship is corrected on a basis of the measured film thickness distribution, the measured pressing force distribution, the measured distance distribution, and the first relationship so that the film thickness distribution falls within the target distribution when the film thickness distribution is out of the target distribution.

15. The method according to claim 10, wherein the film thickness distribution is determined from a film thickness difference between two corners out of four corners of the resist layer that the template is brought close to or pressed against.
